(19) United States
(12) Patent Application Publication
(10) Pub. No.: US 2011/0273231 A1
(43) Pub. Date: Nov. 10, 2011

(54) SEMICONDUCTOR INTEGRATED CIRCUIT

(75) Inventor: Kei NAKAMURA, Ukyo-Ku (JP)

(73) Assignee: ROHM CO., LTD., Kyoto (JP)

(21) Appl. No.: 13/011,343

(22) Filed: Jan. 21, 2011

(30) Foreign Application Priority Data
Jan. 22, 2010 (JP) JP2010-011669

(51) Int. Cl. H03F 3/45; H03K 17/687

(52) U.S. Cl. 330/257; 327/427; 330/260

(57) ABSTRACT

A semiconductor integrated circuit receives an input current, and supplies, to a different circuit, an output current that corresponds to the input current. A first terminal of a first variable resistor is connected to an input terminal. A first transistor and a second transistor are sequentially arranged in series between a power supply terminal and a second terminal of the first variable resistor. A third transistor and a fourth transistor are sequentially arranged in series between the power supply terminal and an output terminal. The gates of the first transistor and the third transistor are each connected to the second terminal of the first variable resistor. The gates of the second transistor and the fourth transistor are each connected to the input terminal. The first variable resistor is configured to be capable of switching the resistance value thereof according to the input current.

### BACKGROUND OF THE INVENTION

1. Field of the Invention

The present invention relates to a semiconductor integrated circuit employing a field effect transistor.

2. Description of the Related Art

A semiconductor integrated circuit is configured by combining basic circuit units such as a current source circuit, a current mirror circuit, a differential amplifier, etc., each employing MOSFETs (Metal Oxide Semiconductor Field Effect Transistors). Each circuit unit receives a bias voltage or bias current (which will be collectively referred to as the “bias signal”), and executes a predetermined operation.

For example, as the bias current to be supplied to the amplifier is raised, the operation performance of each transistor rises in a trade-off with increased current consumption, thereby raising the operation speed of the amplifier. That is to say, by switching the bias current according to the kind or the frequency of a signal to be processed, such an arrangement is capable of controlling the operation speed and the current consumption of a circuit.

### RELATED ART DOCUMENTS

### Patent Documents

### [Patent Document 1]

Japanese Patent Application Laid Open No. H10-013166

### [Patent Document 2]

Japanese Patent Application Laid Open No. 2000-165161

### [Patent Document 3]

Japanese Patent Application Laid Open No. 2002-064350

However, if the bias signal is changed, the operating point of each amplifier or the operating point of each of the transistors, which are components of an amplifier or other blocks, also changes. As a result, such an arrangement leads to a problem of deterioration of the operation performance of the circuit.

### SUMMARY OF THE INVENTION

The present invention has been made in view of such a situation. Accordingly, it is an exemplary purpose of the present invention to provide a semiconductor integrated circuit having an advantage of reduced deterioration of the operation performance due to switching of a bias signal.

An embodiment of the present invention relates to a semiconductor integrated circuit configured to receive an input current, and to generate an output current that corresponds to the input current. The semiconductor integrated circuit comprises: an input terminal arranged on a path of the input current; an output terminal arranged on a path of the output current; a first variable resistor arranged such that a first terminal thereof is connected to the input terminal; a first transistor and a second transistor each configured as a field effect transistor, and sequentially arranged in series between a fixed voltage terminal and a second terminal of the first variable resistor; and a third transistor and a fourth transistor each configured as a field effect transistor, and arranged in series between the fixed voltage terminal and the output terminal. The gates of the first transistor and the third transistor are each connected to the second terminal of the first variable resistor. Furthermore, the gates of the second transistor and the fourth transistor are each connected to the input terminal. Moreover, the first variable resistor is configured such that the resistance value thereof is switchable according to the input current.

With such an embodiment, the drain-source voltage of each of the first transistor and the third transistor follows the voltage drop across the first resistor. Thus, by switching the resistance value of the first resistor according to the input current, such an arrangement is capable of controlling the drain-source voltage of each of the first transistor and the third transistor. As a result, such an arrangement suppresses deterioration of the performance of a circuit connected to the first output terminal.

Also, the resistance value of the first variable resistor may be set to a value that is approximately inversely proportional to the current value of the input current such that the voltage drop across the first variable resistor is maintained at a constant level.

Also, the voltage drop across the first variable resistor may be set to a desired value as the drain-source voltage of each of the first transistor and the third transistor.

Also, a semiconductor integrated circuit according to an embodiment may further comprise: a second output terminal; and a fifth transistor arranged between the second output terminal and the fixed voltage terminal such that the gate thereof is connected to the gates of the first transistor and the third transistor so as to form a common gate. Also, a second output current may be output via the second output terminal.

Another embodiment of the present invention relates to a differential amplifier. The differential amplifier comprises: a current source configured to generate a reference current having a current value that can be switched between multiple values; the aforementioned semiconductor integrated circuit configured to receive the reference current as the input current, and to generate an output current that corresponds to the reference current; a differential pair configured to receive, as a tail current, the output current of the semiconductor integrated circuit; and a current mirror circuit connected as an active load to the differential pair.

With such an embodiment, in a case in which the semiconductor integrated circuit is used as a tail current source, such an arrangement suppresses unwanted fluctuation in the output impedance of the tail current source. Thus, such an arrangement suppresses deterioration of the performance of the differential amplifier.

Yet another embodiment of the present invention also relates to a differential amplifier. The differential amplifier comprises: a current source configured to generate a reference current having a current value that can be switched between multiple values; the aforementioned semiconductor integrated circuit configured to receive the reference current as the input current, and to generate an output current that corresponds to the reference current; a differential pair configured to receive, as a tail current, the second output current of the semiconductor integrated circuit; and a current mirror circuit connected as an active load to the differential pair.

With such an embodiment, in a case in which the semiconductor integrated circuit is used as a tail current source, such an arrangement suppresses fluctuation in the output impedance of the tail current source, i.e., fluctuation in the impedance of the fifth transistor. Thus, such an arrangement suppresses deterioration of the performance of the differential amplifier.

Yet another embodiment of the present invention relates to a buffer amplifier configured to receive an input voltage, and to output an output voltage that corresponds to the input voltage. The buffer amplifier comprises: a differential amplifier according to any one of the aforementioned embodiments; an output stage comprising an amplification transistor configured to amplify a signal subjected to differential amplification by the differential amplifier; and a phase compensation circuit comprising a feedback resistor and a feedback capacitor arranged in series between the gate and the drain of the amplification transistor. The input voltage is applied to the gate of a transistor which is one side of the differential pair, and a gate of another transistor which is the other side of the differential pair is connected to an output terminal of the buffer amplifier. The buffer amplifier is configured to be capable of switching at least one from among the resistance value of the feedback resistor and the capacitance of the feedback capacitor according to the reference current.

By switching the compensation amount to be provided by the phase compensation circuit according to the reference current, such an arrangement provides phase compensation according to the operating frequency of the circuit. Thus, such an arrangement provides improvement of the stability of the circuit.

Yet another embodiment of the present invention also relates to a semiconductor integrated circuit configured to receive an input current, and to generate an output current that corresponds to the input current. The semiconductor integrated circuit comprises: an input terminal arranged on a path of the input current; an output terminal arranged on a path of the output current; a sixth transistor and a seventh transistor each configured as a field effect transistor, and sequentially arranged in series between the input terminal and a fixed voltage terminal; an eighth transistor and a ninth transistor each configured as a field effect transistor, and sequentially arranged in series between the output terminal and the fixed voltage terminal; a bias input terminal arranged on a path of a bias current; and a tenth transistor configured as a field effect transistor and a second variable resistor sequentially arranged in series between the bias input terminal and the fixed voltage terminal. The gate and the drain of the tenth transistor are wired together, and the gates of the sixth transistor and the eighth transistor are each connected to the gate of the tenth transistor. Furthermore, the gates of the seventh transistor and the ninth transistor are each connected to the input terminal. Moreover, the second variable resistor is configured such that the resistance value thereof can be switched according to the bias current.

With such an embodiment, the drain-source voltage of each of the seventh transistor and the ninth transistor follows the voltage drop across the second resistor. Thus, by switching the resistance value of the second resistor according to the input current, such an arrangement is capable of controlling the drain-source voltage of each of the seventh transistor and the ninth transistor. As a result, such an arrangement suppresses deterioration of the performance of the semiconductor integrated circuit due to change in the input current.

Also, the resistance value of the second variable resistor may be set to a value that is approximately inversely proportional to the current value of the bias current such that the voltage drop across the second variable resistor is maintained at a constant level.

Also, the voltage drop across the second variable resistor may be set to a desired value as the drain-source voltage of each of the seventh transistor and the ninth transistor.

Also, a semiconductor integrated circuit according to an embodiment may further comprise: a second output terminal; and an eleventh transistor arranged between the second output terminal and the fixed voltage terminal such that the gate thereof is connected to the gate of the tenth transistor so as to form a common gate. Also, the semiconductor integrated circuit may output a second output current via the second output terminal.

Such an arrangement is capable of controlling the drain-source voltage of the eleventh transistor, thereby suppressing deterioration of the performance of a circuit connected to the second output terminal.

Yet another embodiment of the present invention relates to a differential amplifier. The differential amplifier comprises: a current source configured to generate a reference current having a current value which can be switched between multiple values; a differential pair; a current source configured to supply a tail current to the differential pair; and the aforementioned semiconductor integrated circuit connected as an active load to the differential pair so as to receive the reference current as the bias current.

With such an embodiment, in a case in which the semiconductor integrated circuit is used as an active load (current mirror load) to be applied to a differential pair, such an arrangement suppresses fluctuation in the output impedance thereof. Thus, such an arrangement suppresses deterioration of the performance of the differential amplifier.

Yet another embodiment of the present invention relates to a buffer amplifier configured to receive an input voltage, and to output an output voltage that corresponds to the input voltage. The buffer amplifier comprises: the aforementioned differential amplifier; an output stage comprising an amplification transistor configured to amplify a signal subjected to differential amplification by the differential amplifier; and a phase compensation circuit comprising a feedback resistor and a feedback capacitor arranged in series between a gate and a drain of the amplification transistor. The input voltage is applied to the gate of a transistor which is one side of the differential pair, and a gate of another transistor which is the other side of the differential pair is connected to an output terminal of the buffer amplifier. Furthermore, the buffer amplifier is configured to be capable of switching at least one from among the resistance value of the feedback resistor and the capacitance of the feedback capacitor according to the reference current.

By switching the compensation amount to be provided by the phase compensation circuit according to the reference current, such an arrangement provides phase compensation according to the operating frequency of the circuit. Thus, such an arrangement provides improvement of the stability of the circuit.

It is to be noted that any arbitrary combination or rearrangement of the above-described structural components and so forth is effective as and encompassed by the present embodiments.

Moreover, this summary of the invention does not necessarily describe all necessary features so that the invention may also be a sub-combination of these described features.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIGS. 1A and 1B are circuit diagrams showing a configuration of a semiconductor integrated circuit according to a first embodiment;

FIG. 2 is a circuit diagram which shows a configuration of a semiconductor integrated circuit according to a second embodiment;

FIG. 3 is a circuit diagram which shows a configuration of a differential amplifier employing the semiconductor integrated circuits shown in FIG. 1 and FIG. 2; and

FIG. 4 is a circuit diagram which shows a configuration of a buffer amplifier employing the semiconductor integrated circuit shown in FIG. 1 and FIG. 2.

### DETAILED DESCRIPTION OF THE INVENTION

The invention will now be described based on preferred embodiments which do not intend to limit the scope of the present invention but exemplify the invention. All of the features and the combinations thereof described in the embodiment are not necessarily essential to the invention.

In the present specification, the state represented by the phrase “the member A is connected to the member B” includes a state in which the member A is indirectly connected to the member B via another member that does not affect the electric connection therebetween, in addition to a state in which the member A is physically and directly connected to the member B.

Similarly, the state represented by the phrase “the member C is provided between the member A and the member B” includes a state in which the member A is indirectly connected to the member C, or the member B is indirectly connected to the member C via another member that does not affect the electric connection therebetween, in addition to a state in which the member A is directly connected to the member C, or the member B is directly connected to the member C.

### First Embodiment

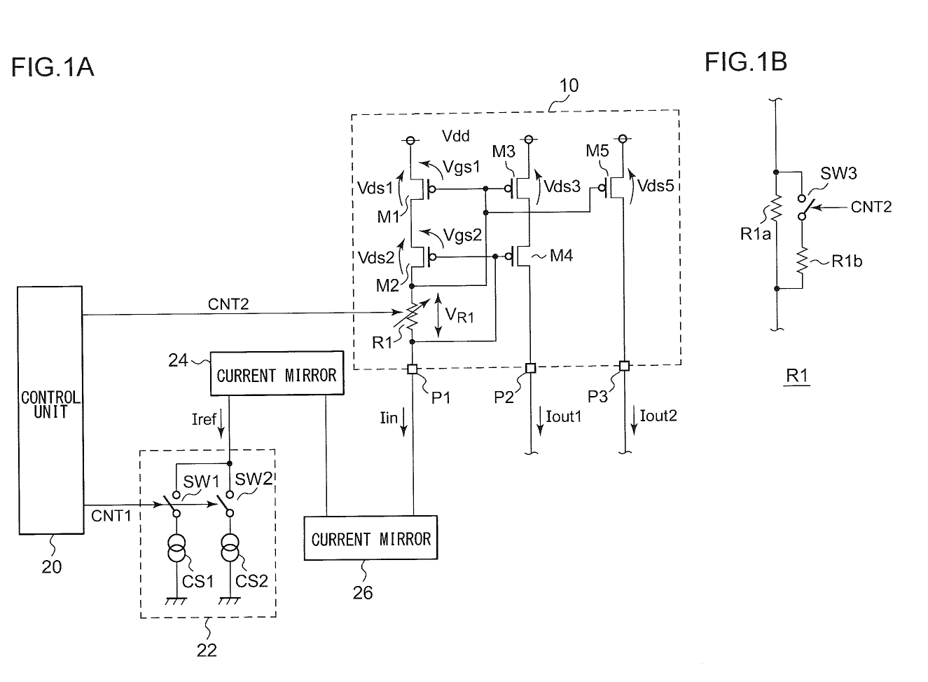

FIGS. 1A and 1B are circuit diagrams showing a configuration of a semiconductor integrated circuit according to a first embodiment. A semiconductor integrated circuit 10 receives an input current Iin, generates an output current Iout1 that corresponds to the input current Iin, and supplies the output current Iout1 thus generated to a different circuit (not shown). The semiconductor integrated circuit 10 is a so-called cascode current mirror circuit.

The semiconductor integrated circuit 10 includes an input terminal P1, a first output terminal P2, a first variable resistor R1, a first transistor M1 through a fourth transistor M4.

The input terminal P1 is arranged on a path of the input current Iin. The first output terminal P2 is arranged on a path of the output current Iout1. A first terminal of the first variable resistor R1 is connected to the input terminal P1.

The first transistor M1 and the second transistor M2 are each configured as the same type of MOSFET, i.e., a P-channel MOSFET, and are sequentially arranged in series between a fixed voltage terminal (power supply terminal Vdd) and a second terminal of the first variable resistor R1. Furthermore, the third transistor M3 and the fourth transistor M4 are each configured as a P-channel MOSFET, and are sequentially arranged in series between the power supply terminal Vdd and the input terminal P2.

The gate of the first transistor M1 and the gate of the third transistor M3 are each connected to the second terminal of the first variable resistor R1. Furthermore, the gate of the second transistor M2 and the gate of the fourth transistor M4 are each connected to the input terminal P1.

A reference current source 22 generates a predetermined reference current Iref. The circuit is configured to switch the reference current Iref between multiple current values. For example, the reference current source 22 includes multiple current sources CS1 and CS2, and multiple switches SW1 and SW2, each configured to switch on and off the corresponding current path. It should be noted that the number of current sources CS and the number of switches SW are not each restricted to 2. Also, the number of current sources CS and the number of switches SW may be a desired number.

Here, with a unit current I generated by the current source CS1, the current 2I generated by the current source CS2 is taken to be double the unit current I. When the switch SW1 is on, the reference current Iref is I, and when the switch SW2 is on, the reference current Iref is 2I.

The reference current Iref generated by the reference current source 22 is controlled by a control unit 20. The control unit 20 generates a control signal CNT1 to be used to control the switches SW1 and SW2 included in the reference current source 22.

The current mirror circuit 24 and the current mirror circuit 26 mirror the reference current Iref, and supply the input current Iin that corresponds to the reference current Iref to the input terminal P1 of the semiconductor integrated circuit 10.

The first variable resistor R1 is configured to be capable of switching the resistance value thereof according to the input current Iin. As described above, the reference current Iref can be varied, and accordingly, the input current Iin is also variable. The control unit 20 controls the reference current Iref, and digitally controls the resistance value of the first variable resistor R1. FIG. 1B is a circuit diagram which shows an example configuration of the first variable resistor R1. The first variable resistor R1 includes multiple resistors R1a and R1b arranged in parallel, and at least one switch SW3. With such an arrangement, the resistance value of the first variable resistor R1 is switched between two values according to the ON/OFF operation of the switch SW3. A control signal CNT2 output from the control unit 20 is input to a control terminal of the switch SW3. Various kinds of variable resistors can be configured by combining multiple resistors and at least one switch, which can be clearly understood by those skilled in this art.

The control unit 20 is preferably configured to set the resistance value of the first variable resistor R1 to a value which is approximately inversely proportional to the current value of the input current Iin, such that the voltage drop V_{R1} across the first variable resistor R1 is maintained at a constant level. In some cases, depending upon the combination of the resistance values and current values, the resistance value of the first variable resistor R1 cannot be set to a value that is exactly inversely proportional to the current value of the input current Iin. Here, being “approximately inversely proportional” encompasses an operation of selecting, in such a case, a value from among multiple values that is closest to being inversely proportional to the current value of the input current Iin.

With such an arrangement, the voltage drop V_{R1} across the first variable resistor R1 is set to a desired value as the drain-source voltage Vds of the first transistor M1 as well as the third transistor M3.

The above is the configuration of the semiconductor integrated circuit 10. Next, description will be made regarding the operation thereof. In FIG. 1A, the following relation holds true.

V_{R1}+Vgs1=Vgs2+Vds1

Here, assuming that Vgs1 is approximately equal to Vgs2, V_{R1} is approximately equal to Vds1.

Furthermore, the relation Vds1+Vgs2=Vgs4+Vds3 holds true. Accordingly, by configuring the first transistor M1 and the third transistor M3 with the same size, and by configuring the second transistor M2 and the fourth transistor with the same size, the relations Vgs2=Vgs4, and Vds1=Vds3 each hold true.

When the input current Iin is changed, there is a corresponding change in the output current Iout. If the resistance value of the first variable resistor R1 is maintained at a constant level, the drain-source voltage Vds3 of the third transistor M3 changes in proportion to the input current Iin. For example, with Vds3=0.3 V with respect to a given input current Iin, when the input current Iin is doubled, Vds3 changes and becomes 0.6 V. Such a change in the drain-source voltage Vds3 changes the operating point of a circuit connected to the first output terminal P2. Accordingly, switching of the input current Iin leads to deterioration of the circuit performance.

In contrast, the semiconductor integrated circuit 10 shown in FIG. 1A suppresses unwanted fluctuation in the voltage drop V_{R1} across the first variable resistor R1, i.e., unwanted fluctuation in the drain-source voltage Vds3 of the third transistor M3. Thus, such an arrangement suppresses unwanted fluctuation in the impedance of the semiconductor integrated circuit 10 as viewed from a circuit connected to the first output terminal P2. This reduces deterioration of the performance of the circuit connected as a load to the first output terminal P2.

The semiconductor integrated circuit 10 shown in FIG. 1A further includes a second output terminal P3 and a fifth transistor M5.

The fifth transistor M5 is configured as a P-channel MOSFET, which is the same type of transistor as the first transistor M1 and the third transistor M3. The fifth transistor M5 is arranged between the second output terminal P3 and the power supply terminal Vdd. The gate of the fifth transistor M5 is connected to the gates of the first transistor M1 and the third transistor M3 as a common gate, and the source of the fifth transistor M5 is connected to the sources of the first transistor M1 and the third transistor M3 as a common source, thereby forming a current mirror circuit. The semiconductor integrated circuit 10 outputs, via the second output terminal P3, a second output current Iout2 that corresponds to the input current Iin.

### Second Embodiment

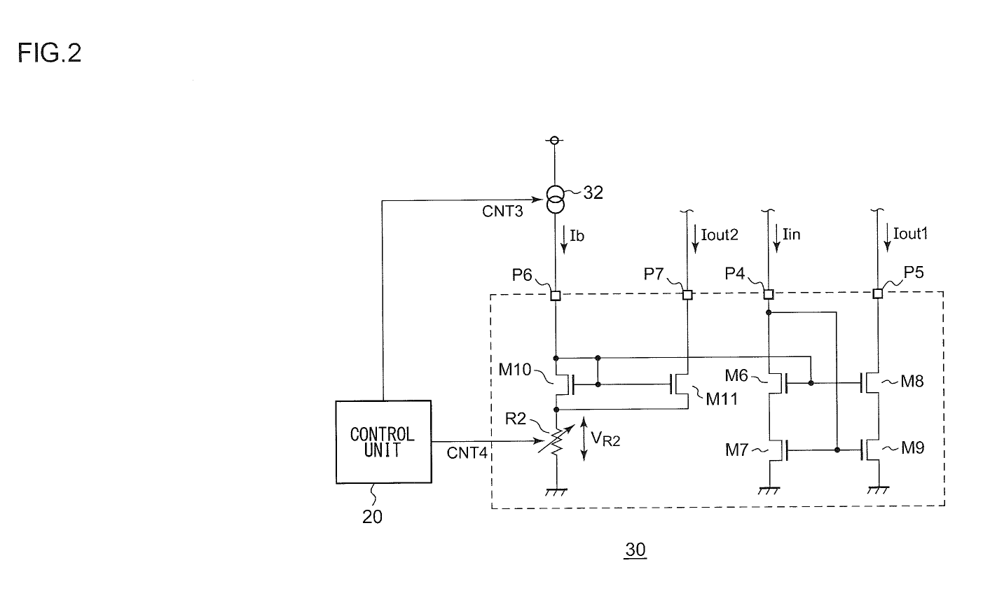

FIG. 2 is a circuit diagram which shows a configuration of a semiconductor integrated circuit 30 according to a second embodiment. The semiconductor integrated circuit 30 shown in FIG. 2 is configured as a low-voltage cascode current mirror circuit, and includes a sixth transistor M6 through a tenth transistor M10, and a second variable resistor R2. The semiconductor integrated circuit 30 receives an input current Iin, and outputs an output current Iout1 that corresponds to the input current Iin.

An input terminal P4 is arranged on a path of the input current Iin, and a first output terminal P5 is arranged on a path of the output current Iout1. The sixth transistor M6 and the seventh transistor M7 are each configured as the same type of transistor, i.e., as an N-channel MOSFET, and are sequentially arranged in series between the input terminal P4 and a fixed voltage terminal (ground terminal). Furthermore, the eighth transistor M8 and the ninth transistor M9 are each configured as an N-channel MOSFET, and are sequentially arranged in series between the first output terminal P5 and the ground terminal.

A bias current source 32 generates a bias current Ib having a variable current value. A control unit 20 digitally controls the value of the bias current Ib according to a control signal CNT3.

A bias input terminal P6 is arranged on a path of the bias current Ib supplied from an external circuit. The tenth transistor M10 and the second variable resistor R2 are sequentially arranged in series between the bias input terminal P6 and the ground terminal. The tenth transistor M10 is configured as an N-channel MOSFET which is the same type as the sixth transistor M6.

The gate and the drain of the tenth transistor M10 are wired together. The gate of the sixth transistor M6 and the gate of the eighth transistor M8 are each connected to the gate of the tenth transistor M10. The gate of the seventh transistor M7 and the gate of the ninth transistor M9 are each connected to the input terminal P4.

The control unit 20 switches the resistance value of the second variable resistor R2 according to the bias current Ib. The second variable resistor R2 should be configured in the same way as the first variable resistor R1 shown in FIG. 1. The control signal CNT4 output from the control unit 20 is input to the second variable resistor R2.

The resistance value of the second variable resistor R2 is set to a value that is approximately inversely proportional to the current value of the bias current Ib such that the voltage drop V_{R2} across the second variable resistor R2 is maintained at a constant level. Furthermore, the voltage drop V_{R2} across the second variable resistor R2 is set to a desired value as the drain-source voltage Vds7 of the seventh transistor M7 and the drain-source voltage Vds9 of the ninth transistor M9.

With the semiconductor integrated circuit 30 shown in FIG. 2, if the resistance value of the second variable resistor R2 is constant, the voltage drop V_{R2} across the second variable resistor R2 changes in proportion to the bias current Ib. As a result, the drain-source voltage Vds7 of the seventh transistor M7 and the drain-source voltage Vds9 of the ninth transistor M9 each change according to the bias current Ib. That is to say, this leads to unwanted fluctuation in the impedance of the internal circuit of the semiconductor integrated circuit 30 as viewed from the input terminal P4 and the first output terminal P5. This leads to unwanted fluctuation in and deterioration of the performance of circuits connected to the input terminal P4 and the first output terminal P5.

In contrast, with the semiconductor integrated circuit 30 shown in FIG. 2, the impedance of the semiconductor integrated circuit 30 can be maintained at a constant level even if the bias current Ib is switched. Thus, such an arrangement suppresses deterioration of the performance of circuits connected to the input terminal P4 and the first output terminal P5.

The semiconductor integrated circuit 30 shown in FIG. 2 further includes a second output terminal P7 and an eleventh transistor M11. The eleventh transistor M11 is configured as an N-channel MOSFET, which is the same type as the tenth transistor M10. The eleventh transistor M11 is arranged such that the gate and the source thereof are respectively connected to the gate and the source of the tenth transistor M10 as a common gate and a common source, thereby forming a current mirror circuit. The semiconductor integrated circuit 30 outputs, via the second output terminal P7, a second output current Iout2 that corresponds to the bias current Ib.

With the semiconductor integrated circuit 30, the bias current Ib is mirrored by the eleventh transistor M11 thus provided, thereby generating the second output current Iout2 that corresponds to the mirrored bias current Ib.

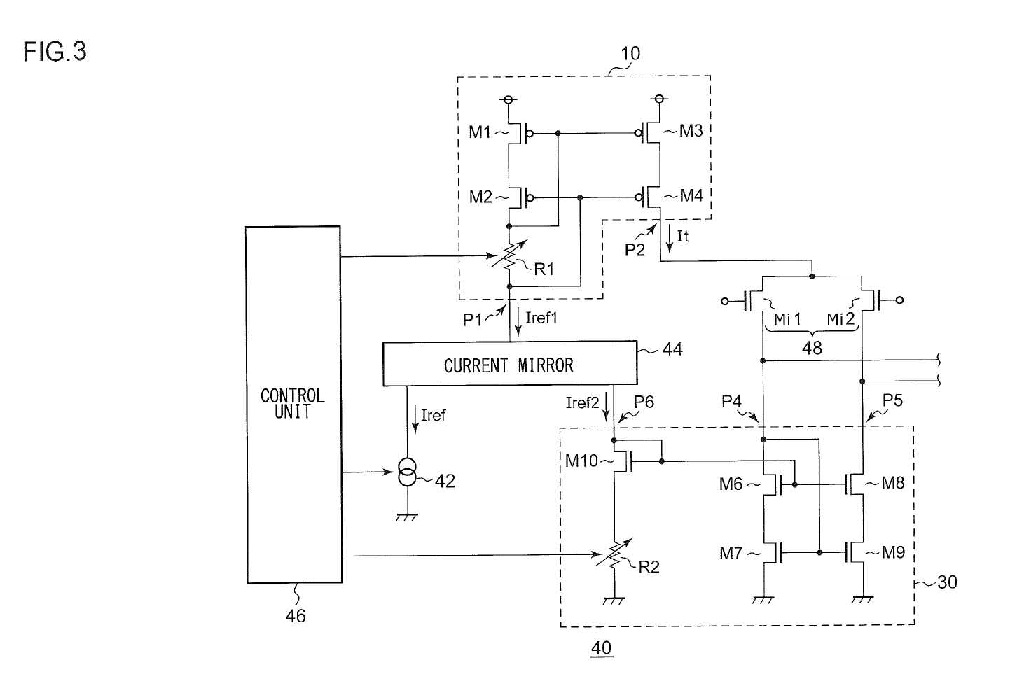

Next, description will be made regarding a specific circuit configuration employing the semiconductor integrated circuits 10 and 30. FIG. 3 is a circuit diagram which shows a configuration of a differential amplifier 40 employing the semiconductor integrated circuits 10 and 30 shown in FIGS. 1 and 2.

The differential amplifier 40 includes the semiconductor integrated circuit 10 shown in FIG. 1, the semiconductor integrated circuit 30 shown in FIG. 2, a reference current source 42, a current mirror circuit 44, a control unit 46, and a differential pair 48.

The differential pair 48 includes input transistors Mi1 and Mi2 arranged such that their sources are connected together. The input transistors Mi1 and Mi2 function as a differential input terminal of the differential amplifier 40.

The reference current source 42 generates a reference current Iref which can be switched between multiple values. The control unit 46 controls the reference current source 42 so as to switch the reference current Iref. The current mirror circuit 44 receives the reference current Iref, and mirrors the reference current Iref so as to generate a first reference current Iref1 and a second reference current Iref2.

The semiconductor integrated circuit 10 receives, via the input terminal P1 thereof, the first reference current Iref as an input current, generates an output current It that corresponds to the first reference current Iref1, and outputs the output current It thus generated via the first output terminal P2. The output current It of the semiconductor integrated circuit 10 is supplied as a tail current to the differential pair 48. It should be noted that the output current output via the first output terminal P5 (not shown) may also be used as such a tail current to be supplied to the differential pair 48, instead of the output current output via the input terminal P4.

The semiconductor integrated circuit 30 is configured as a current mirror circuit connected as an active load to the differential pair 48. The semiconductor integrated circuit 30 receives, via the bias input terminal P6 thereof, the second reference current Iref2 as the bias current.

The control unit 46 controls the first variable resistor R1 included in the semiconductor integrated circuit and the second variable resistor R2 included in the semiconductor integrated circuit 30 according to the reference current Iref.

The above is the configuration of the differential amplifier 40. Description will be made regarding a case in which the differential amplifier 40 is employed in a switched-capacitor circuit. In a case in which the sampling frequency of the switched-capacitor circuit is switched, the bias state of the differential amplifier 40 is switched according to the sampling frequency. For example, in a case in which the sampling frequency can be switched between 64-times oversampling and 128-times oversampling, the reference current Iref is switched between a given current value I and a current value 2I that is double the current value I.

With the differential amplifier 40, when the reference current Iref is switched according to the sampling frequency, the resistance values of the first variable resistor R1 and the second variable resistor R2 are each switched. Thus, such an arrangement is capable of suppressing unwanted fluctuation in the operating point, in other words, of suppressing unwanted fluctuation in the impedance, of each transistor which is a component of the semiconductor integrated circuit 10 or semiconductor integrated circuit 30.

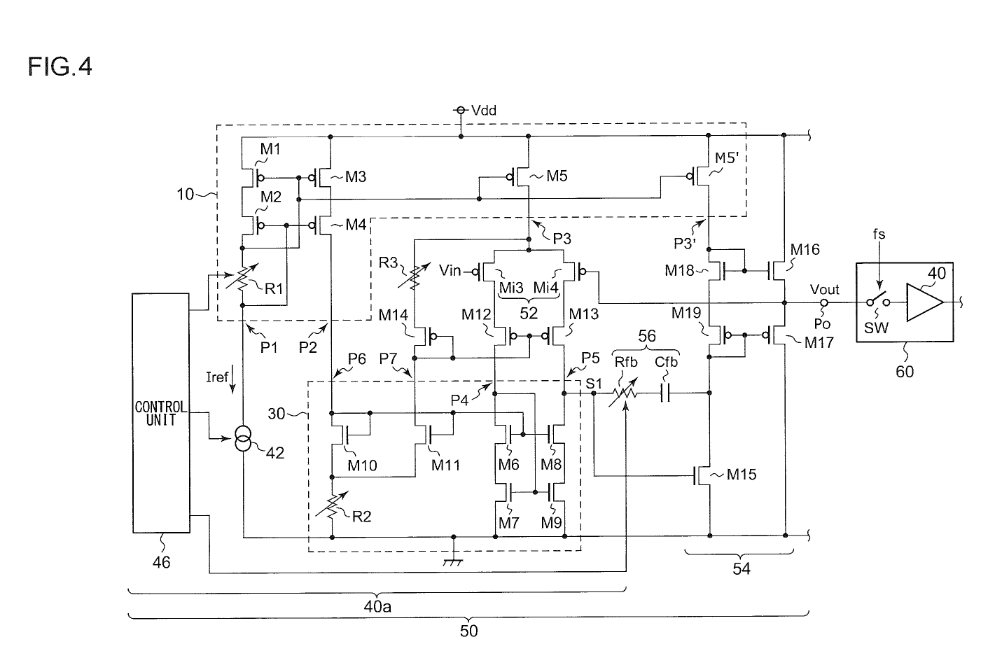

FIG. 4 is a circuit diagram which shows a configuration of a buffer amplifier 50 employing the semiconductor integrated circuits 10 and 30 shown in FIGS. 1 and 2. As shown in FIG. 4, the buffer amplifier 50 receives an input voltage Vin, and outputs an output voltage Vout that corresponds to the input voltage Vin. The output voltage Vout is output to a switched-capacitor circuit 60. The switched-capacitor circuit 60 is configured by combining capacitors, switches, and the differential amplifier 40. However, the configuration thereof is not restricted in particular. The switched-capacitor circuit 60 is a suitable application of the differential amplifier 40 shown in FIG. 3.

The buffer amplifier 50 includes a differential amplifier 40a, an output stage 54, and a phase compensation circuit 56. The differential amplifier 40a has the same basic configuration as that of the differential amplifier 40 shown in FIG. 3. The differential amplifier 40a includes a differential pair 52, a semiconductor integrated circuit 10, and a semiconductor integrated circuit 30. The semiconductor integrated circuit 10 supplies, to the differential pair 52, a tail current output via the second output terminal P3 thereof.

The semiconductor integrated circuit 30 is connected as an active load to the differential pair 52. Transistors M12 and M13 are arranged between the differential pair 52 and the semiconductor integrated circuit 30.

A third variable resistor R3 and a transistor M14 are sequentially arranged in series between the second output terminal P3 of the semiconductor integrated circuit 10 and the second output terminal P7 of the semiconductor integrated circuit 30. The gate of the transistor M14 is connected to the second output terminal P7 together with the gates of the transistors M12 and M13.

Due to differential amplification by means of the differential amplifier 40a, a signal S1 occurs at a connection node (output terminal P5) that connects the transistor M13 and the transistor M8. The output stage 54 amplifies the signal S1 thus subjected to differential amplification, and outputs the signal thus amplified via an output terminal Po.

The output stage 54 includes an amplification transistor M15, output transistors M16 and M17, and bias transistors M18 and M19. The output transistors M16 and M17 form a push-pull output circuit. The semiconductor integrated circuit 10 outputs, via an output terminal P3′, a current that corresponds to the reference current Iref. The output stage 54 is biased by the current received from the output terminal P3′. It should be noted that the configuration of the output stage 54 is not restricted to such a configuration shown in FIG. 4. Also, various kinds of topologies may be employed.

The phase compensation circuit 56 includes a feedback resistor Rfb and a feedback capacitor Cfb arranged in series between the gate and the drain of the amplification transistor M15.

The input voltage Vin is applied to the gate (non-inverting input terminal) of the transistor Mi3 which is one side of the differential pair 52. Furthermore, the gate (inverting input terminal) of the transistor Mi4 which is the other side of the differential pair 52 is connected to the output terminal Po of the buffer amplifier 50.

Such an arrangement is configured such that at least one of either the resistance value of the feedback resistor Rfb or the capacitance value of the feedback capacitor Cfb can be switched according to the reference current Iref. In FIG. 4, the capacitance value of the feedback capacitor Cfb is fixed, and the resistance value of the feedback resistor Rfb is variable.

The switched-capacitor circuit 60 is configured such that the switching frequency fs thereof is switchable. The control unit 46 switches the reference current Iref generated by the reference current source 42, according to the switching frequency fs. For example, the reference current Iref is set to a value which is proportional to the switching frequency fs.

As a result, when the switching frequency fs is low, and, accordingly, when it is acceptable to lower the performance of the buffer amplifier 50, such an arrangement allows the circuit to operate with low current consumption. Furthermore, by switching the resistance values of the first variable resistor R1 and the second variable resistor R2 according to the reference current Iref, such an arrangement is capable of suppressing deterioration of the performance of the buffer amplifier 50.

Switching the reference current Iref leads to change in the bias state of the buffer amplifier 50. Accordingly, the frequency characteristics or stability (phase margin) of the circuit change according to the change in the bias state. The control unit 46 switches the resistance value of the feedback resistor Rfb according to the switching of the reference current Iref, which accompanies the switching of the switching frequency fs.

The resistance value of the feedback resistor Rfb is preferably set to a value that is proportional to 1/(√fs). For example, in a case in which the switching frequency fs can be switched between two states, such as 64-times oversampling and 128-times oversampling, the resistance value Rfb64 to be used at the time of 64-times oversampling is preferably set to a value approximately 1.4 times the resistance value Rfb128 to be used at the time of 128-times oversampling.

It should be noted that a typical variable resistor is configured by combining multiple resistor elements each having the same resistance value. Accordingly, such a variable resistor cannot necessarily provide a resistance value that is proportional to 1/(√fs). In this case, such an arrangement should select a resistance value closest to or next-closest to the value that is proportional to 1/(√fs). For example, let us consider an arrangement in which the feedback resistor Rfb includes six resistor elements each having a resistance of 6 kΩ. With such an arrangement, at the time of 64-times oversampling, four resistor elements connected in parallel provide a combined resistance of 1.5 kΩ, but by connecting the six resistor elements in parallel, such an arrangement provides a combined resistance of 1 kΩ, thereby providing a resistance value that is closer to a value 1/(√fs) times the resistance value to be used at the time of 64-times oversampling.

By switching the resistance value of the feedback resistor Rfb according to the switching frequency, i.e., the reference current Iref, such an arrangement provides improved stability of the buffer amplifier 50.

Description has been made regarding the present invention with reference to the embodiments. The above-described embodiment has been described for exemplary purposes only, and is by no means intended to be interpreted restrictively. Rather, it can be readily conceived by those skilled in this art that various modifications may be made by making various combinations of the aforementioned components or processes, which are also encompassed in the technical scope of the present invention. Description will be made below regarding such modifications.

In the aforementioned various kinds of circuits, an arrangement may be made in which each N-channel MOSFET is replaced by a P-channel MOSFET, each P-channel MOSFET is replaced by an N-channel MOSFET, and the power supply voltage and the ground voltage (or negative power supply voltage) are mutually exchanged (inverted).

Description has been made with reference to FIGS. 3 and 4 regarding an amplifier circuit having differential input and single-ended output. However, the present invention is not restricted to such an arrangement. Also, the present invention can be applied to a fully-differential amplifier circuit having differential input and differential output.

Description has been made with reference to the buffer amplifier 50 shown in FIG. 4 regarding an arrangement in which the feedback resistor Rfb is variable. Also, the feedback capacitor Cfb may be configured as a variable capacitor. Also, both the feedback resistor Rfb and the feedback capacitor Cfb may be variable.

While the preferred embodiments of the present invention have been described using specific terms, such description is for illustrative purposes only, and it is to be understood that changes and variations may be made without departing from the spirit or scope of the appended claims.

What is claimed is:

1. A semiconductor integrated circuit configured to receive an input current, and to supply an output current that corresponds to the input current to another circuit, the semiconductor integrated circuit comprising:
an input terminal arranged on a path of the input current;
an output terminal arranged on a path of the output current;
a first variable resistor arranged such that a first terminal thereof is connected to the input terminal;
a first transistor and a second transistor each configured as a field effect transistor, and sequentially arranged in series between a fixed voltage terminal and a second terminal of the first variable resistor; and
a third transistor and a fourth transistor each configured as a field effect transistor, and arranged in series between the fixed voltage terminal and the output terminal,
wherein the gates of the first transistor and the third transistor are each connected to the second terminal of the first variable resistor,
and wherein the gates of the second transistor and the fourth transistor are each connected to the input terminal,
and wherein the first variable resistor is configured such that the resistance value thereof is switchable according to the input current.

2. A semiconductor integrated circuit according to claim 1, wherein the resistance value of the first variable resistor is set to a value that is approximately inversely proportional to the current value of the input current such that the voltage drop across the first variable resistor is maintained at a constant level.

3. A semiconductor integrated circuit according to claim 1, wherein the voltage drop across the first variable resistor is set to a desired value as the drain-source voltage of each of the first transistor and the third transistor.

4. A semiconductor integrated circuit according to claim 1, further comprising:
a second output terminal; and
a fifth transistor arranged between the second output terminal and the fixed voltage terminal such that the gate thereof is connected to the gates of the first transistor and the third transistor so as to form a common gate,
wherein a second output current is output via the second output terminal.

5. A differential amplifier comprising:
a current source configured to generate a reference current having a current value that can be switched between a plurality of values;
a semiconductor integrated circuit according to claim 1, configured to receive the reference current as the input current, and to generate an output current that corresponds to the reference current;
a differential pair configured to receive, as a tail current, the output current of the semiconductor integrated circuit; and
a current mirror circuit connected as an active load to the differential pair.

6. A differential amplifier comprising:
a current source configured to generate a reference current having a current value that can be switched between a plurality of values;
a semiconductor integrated circuit according to claim 4, configured to receive the reference current as the input current, and to generate an output current that corresponds to the reference current;
a differential pair configured to receive, as a tail current, the second output current of the semiconductor integrated circuit; and
a current mirror circuit connected as an active load to the differential pair.

7. A buffer amplifier configured to receive an input voltage, and to output an output voltage that corresponds to the input voltage, the buffer amplifier comprising:
a differential amplifier according to claim 5;
an output stage comprising an output transistor configured to amplify a signal subjected to differential amplification by the differential amplifier; and
a phase compensation circuit comprising a feedback resistor and a feedback capacitor arranged in series between the gate and the drain of the output transistor,
wherein the input voltage is applied to the gate of a transistor which is one side of the differential pair, and a gate of another transistor which is the other side of the differential pair is connected to an output terminal of the buffer amplifier,
and wherein the buffer amplifier is configured to be capable of switching at least one from among the resistance value of the feedback resistor and the capacitance of the feedback capacitor according to the reference current.

8. A semiconductor integrated circuit configured to receive an input current, and to supply, to another circuit, an output current that corresponds to the input current, the semiconductor integrated circuit comprising:
an input terminal arranged on a path of the input current;
an output terminal arranged on a path of the output current;
a sixth transistor and a seventh transistor each configured as a field effect transistor, and sequentially arranged in series between the input terminal and a fixed voltage terminal;
an eighth transistor and a ninth transistor each configured as a field effect transistor, and sequentially arranged in series between the output terminal and the fixed voltage terminal;
a bias input terminal arranged on a path of a bias current; and
a tenth transistor configured as a field effect transistor and a second variable resistor sequentially arranged in series between the bias input terminal and the fixed voltage terminal,
wherein the gate and the drain of the tenth transistor are wired together, and the gates of the sixth transistor and the eighth transistor are each connected to the gate of the tenth transistor,
and wherein the gates of the seventh transistor and the ninth transistor are each connected to the input terminal,
and wherein the second variable resistor is configured such that the resistance value thereof can be switched according to the bias current.

9. A semiconductor integrated circuit according to claim 8, wherein the resistance value of the second variable resistor is set to a value that is approximately inversely proportional to the current value of the bias current such that the voltage drop across the second variable resistor is maintained at a constant level.

10. A semiconductor integrated circuit according to claim 8, wherein the voltage drop across the second variable resistor is set to a desired value as the drain-source voltage of each of the seventh transistor and the ninth transistor.

11. A semiconductor integrated circuit according to claim 8, further comprising:
a second output terminal; and
an eleventh transistor arranged between the second output terminal and the fixed voltage terminal such that the gate thereof is connected to the gate of the tenth transistor,
wherein a second output current is output via the second output terminal.

12. A differential amplifier comprising:
a current source configured to generate a reference current having a current value which can be switched between a plurality of values;
a differential pair;
a current source configured to supply a tail current to the differential pair; and
a semiconductor integrated circuit according to claim 8, connected as an active load to the differential pair so as to receive the reference current as the bias current.

13. A buffer amplifier configured to receive an input voltage, and to output an output voltage that corresponds to the input voltage, the buffer amplifier comprising:
a differential amplifier according to claim 12;
an output stage comprising an output transistor configured to amplify a signal subjected to differential amplification by the differential amplifier; and
a phase compensation circuit comprising a feedback resistor and a feedback capacitor arranged in series between a gate and a drain of the output transistor,
wherein the input voltage is applied to the gate of a transistor which is one side of the differential pair, and a gate of another transistor which is the other side of the differential pair is connected to an output terminal of the buffer amplifier,
and wherein the buffer amplifier is configured to be capable of switching at least one from among the resistance value of the feedback resistor and the capacitance of the feedback capacitor according to the reference current.

14. A semiconductor integrated circuit configured to receive an input current, and to output an output current that corresponds to the input current, the semiconductor integrated circuit comprising:
a first transistor and a second transistor each configured as a field effect transistor, and a first variable resistor, which are sequentially arranged in series on a path of the input current; and
a third transistor and a fourth transistor each configured as a field effect transistor, and sequentially arranged in series on a path of the output current,
wherein the gates of the first transistor and the third transistor are each connected to a second transistor side terminal of the first variable resistor, and the sources of the first transistor and the third transistor are each connected to a fixed voltage terminal at which the electric potential is fixed,
and wherein the gates of the second transistor and the fourth transistor are each connected to the other terminal of the first variable resistor, which is the terminal on the side opposite to the second transistor,
and wherein the first variable resistor is configured such that the resistance value thereof is switchable according to the input current.

15. A semiconductor integrated circuit according to claim 14, wherein the resistance value of the first variable resistor is set to a value that is approximately inversely proportional to the current value of the input current such that the voltage drop across the first variable resistor is maintained at a constant level.

16. A semiconductor integrated circuit according to claim 14, wherein the voltage drop across the first variable resistor is set to a desired value as the drain-source voltage of each of the first transistor and the third transistor.

17. A semiconductor integrated circuit according to claim 14, further comprising a fifth transistor arranged such that the gate thereof is connected to each of the gates of the first transistor and the third transistor, and the source thereof is connected to the fixed voltage terminal,
wherein a second output current that flows through the fifth transistor is output.

18. A differential amplifier comprising:
a current source configured to generate a reference current having a current value that can be switched between a plurality of values;
a semiconductor integrated circuit according to claim 14, configured to receive the reference current as the input current, and to generate an output current that corresponds to the reference current;
a differential pair configured to receive the output current of the semiconductor integrated circuit as a tail current; and
a current mirror circuit connected as an active load to the differential pair.

19. A differential amplifier comprising:
a current source configured to generate a reference current having a current value that can be switched between a plurality of values;
a semiconductor integrated circuit according to claim 17, configured to receive the reference current as the input current, and to generate an output current that corresponds to the reference current;
a differential pair configured to receive the second output current of the semiconductor integrated circuit as a tail current; and
a current mirror circuit connected as an active load to the differential pair.

20. A buffer amplifier configured to receive an input voltage, and to output an output voltage that corresponds to the input voltage, the buffer amplifier comprising:
a differential amplifier according to claim 18;
an output stage comprising an output transistor configured to amplify a signal subjected to differential amplification by the differential amplifier; and
a phase compensation circuit comprising a feedback resistor and a feedback capacitor arranged in series between a gate and a drain of the output transistor,
wherein the input voltage is applied to the gate of a transistor which is one side of the differential pair, and a gate of another transistor which is the other side of the differential pair is connected to an output terminal of the buffer amplifier,
and wherein the buffer amplifier is configured to be capable of switching at least one from among the resistance value of the feedback resistor and the capacitance of the feedback capacitor according to the reference current.

21. A semiconductor integrated circuit configured to receive an input current, and to output an output current that corresponds to the input current, the semiconductor integrated circuit comprising:
a sixth transistor and a seventh transistor each configured as a field effect transistor, and sequentially arranged in series on a path of the input current;
an eighth transistor and a ninth transistor each configured as a field effect transistor, and sequentially arranged in series on a path of the output current;
a tenth transistor configured as a field effect transistor and a second variable resistor which are sequentially arranged in series on a path a bias current,
wherein a gate and a drain of the tenth transistor are wired together, and gates of the sixth transistor and the eighth transistor are each connected to a gate of the tenth transistor,
and wherein gates of the seventh transistor and the ninth transistor are each connected to a terminal of the sixth transistor, which is a terminal on a side opposite to the seventh transistor,
and wherein the second variable resistor is configured such that the resistance value thereof is switchable according to the bias current.

22. A semiconductor integrated circuit according to claim 21, wherein the resistance value of the second variable resistor is set to a value that is approximately inversely proportional to the current value of the bias current such that the voltage drop across the second variable resistor is maintained at a constant level.

23. A semiconductor integrated circuit according to claim 21, wherein the voltage drop across the second variable resistor is set to a desired value as the drain-source voltage of each of the seventh transistor and the ninth transistor.

24. A semiconductor integrated circuit according to claim 21, further comprising an eleventh transistor arranged such that a gate thereof is connected to the gate of the tenth transistor,
wherein a second output current that flows through the eleventh transistor is output.

25. A differential amplifier comprising:
a current source configured to generate a reference current having a current value which can be switched between a plurality of values;
a differential amplifier;
a current source configured to supply a tail current to the differential pair; and
a semiconductor integrated circuit according to claim 21, connected as an active load to the differential pair, and configured to receive the reference current as the bias current.

26. A buffer amplifier configured to receive an input voltage, and to output an output voltage that corresponds to the input voltage, the buffer amplifier comprising:
a differential amplifier according to claim 25;
an output stage comprising an output transistor configured to amplify a signal subjected to differential amplification by the differential amplifier; and
a phase compensation circuit comprising a feedback resistor and a feedback capacitor arranged in series between a gate and a drain of the output transistor,
wherein the input voltage is applied to the gate of a transistor which is one side of the differential pair, and a gate of another transistor which is the other side of the differential pair is connected to an output terminal of the buffer amplifier,
and wherein the buffer amplifier is configured to be capable of switching at least one from among the resistance value of the feedback resistor and the capacitance of the feedback capacitor according to the reference current.
